(19) United States
(12) Patent Application Publication
(10) Pub. No.: US 2015/0207442 A1
(43) Pub. Date: Jul. 23, 2015

(54) INTELLIGENT POWER MODULE WITH SNUBBER CAPACITOR FOR SURGE REDUCTION

(71) Applicant: SAMSUNG ELECTRO-MECHANICS CO., LTD., Suwon-Si (KR)

(72) Inventor: Jun-Ho LEE, Suwon-Si (KR)

(21) Appl. No.: 14/505,267

(22) Filed: Oct. 2, 2014

(30) Foreign Application Priority Data
Jan. 22, 2014 (KR) 10-2014-0008025

(51) Int. Cl. H02P 6/14; H01L 23/62

(52) U.S. Cl. CPC H02P 6/14; H01L 23/62

(57) ABSTRACT

An intelligent power module having a snubber capacitor for surge reduction installed therein is disclosed. IPM having a snubber capacitor according to an embodiment of the present invention can prevent a device from malfunctioning or being destroyed by a surge voltage. An embodiment of the present invention can allow for easy design of the IPM and reduction of an area and cost of a PCB

### CROSS-REFERENCE TO RELATED APPLICATIONS

This application claims the benefit of Korean Patent Application No. 10-2014-0008025, filed with the Korean Intellectual Property Office on Jan. 22, 2014, the disclosure of which is incorporated herein by reference in its entirety.

### BACKGROUND

1. Technical Field

The present invention relates to an intelligent power module (IPM) having a snubber capacitor installed therein for reduction of surge.

2 Background Art Intelligent power modules (IPMs) have a power semiconductor device, such as IGBT, MOSFET, FRD, etc., a control circuit, a driver circuit, a safety circuit and a control power configured within a single package, and have a variety of I/O voltammetry, control methods, shapes and sizes depending on their use and system requirement. Universal inverters, numerical control (NC) machine tools and industrial robots, which are applied devices in the field of power electronics, require to be more efficient and smaller to keep up with their advancement. To meet with the requirement for a smaller and more functional device, the IGBT reduces the number of peripheral circuits and components by installing the driver circuit and various safety circuits within a module package and shortens a time taken for system design. Moreover, the EMI property and the immunity to the parasitic effect are improved because the length of wiring between a driver circuit and a power switching device in the IPM is short.

In the early days of developing the IPM, the driver circuit or safety circuit was simply inserted into a conventional power device module, with BJT and MOSFET for the main device and thick and thin ICs for the control unit. Recently, IGBT and MOSFET devices and dedicated ICs are mostly installed. This is because an optimal design is increasingly required by considering the system, device, control and safety functions comprehensively, instead of simply installing the control circuit, etc. in a single module.

Therefore, the IPM needs to be designed to satisfy the requirements of high-speed switching, low loss, an optimal trade-off design for SOA (safe operating area), proper safety measures, short Toff, high noise stability and smaller and lighter switching device (high integration) that are differentiated from using individual devices, while considering the system aspect of low noise (high frequency), high efficiency (low loss), ruggedness, consistent control, small and lighter device and easy design and assembly.

Moreover, a dedicated IC for driving and protecting the power device in an optimal state needs to be adopted, and ultimately a high-integration package technology, in which noise resistance, surge voltage, thermal dissipation characteristics and size are considered, is required.

The IPM technology developed by most power semiconductor manufacturers have been focused on developing IGBT devices for meeting the system requirements, FWDs (free-wheeling diodes) for protecting the device and reducing the loss, control and safety circuits and packages having better characteristics.

### SUMMARY

An embodiment of the present invention provides an IPM having a snubber capacitor for surge reduction installed therein that can prevent a device from malfunctioning or being destroyed by a surge voltage.

Another embodiment of the present invention provides an IPM having a snubber capacitor for surge reduction installed therein that can allow for easy design of the IPM and reduction of an area and cost of a PCB.

An embodiment of the present invention provides an intelligent power module having a snubber capacitor for surge reduction installed therein that includes: a drive IC configured to receive a first voltage signal from a micro controller unit and generate a second voltage signal; a switch configured to receive the second voltage signal from the drive IC and generate a motor driving signal for driving a motor based on the second voltage signal; and a surge reducer connected in between the switch and the motor and configured to reduce a surge voltage.

In an embodiment, the surge reducer can be installed inside the intelligent power module, and the surge reducer can include a capacitor, which can be a multi-layer ceramic capacitor (MLCC). The capacitor can have more than one capacitor connected in parallel therein.

In another embodiment, a capacitance of the capacitor can be adjusted according to a request by a user. The switch can include a first sub-switch and a second sub-switch, and the surge reducer can be connected to one end of the first sub-switch and one end of the second sub-switch. The first sub-switch can include a first switch, a second switch and a third switch, and the second sub-switch can include a fourth switch, a fifth switch and a sixth switch, wherein one end of the surge reducer can be connected to an output terminal of the first switch, an output terminal of the second switch and an output terminal of the third switch, and wherein the other end of the surge reducer can be connected to an input terminal of the fourth switch, an input terminal of the fifth switch and an input terminal of the sixth switch.

In yet another embodiment, an input terminal of the first switch, an input terminal of the second switch and an input terminal of the third switch can be each connected with the motor, and the first switch, the second switch, the third switch, the fourth switch, the fifth switch and the sixth switch can each include at least one selected from the group consisting of GTO (Gate Turn-off Thyristor), MOSFET, IGBT (Insulated Gate Bipolar Transistor) and MCT (MOS-Controlled Thyristor). The first voltage signal can be smaller than the second voltage signal.

A still another embodiment of the present invention can provide a home electronic appliance including the intelligent power module having a snubber capacitor for surge reduction installed therein.

### BRIEF DESCRIPTION OF THE DRAWINGS

FIG. 1 is a block diagram showing an IPM having a snubber capacitor for surge reduction installed therein in accordance with an embodiment of the present invention.

FIG. 2 shows an internal configuration of the IPM having a snubber capacitor for surge reduction installed therein in accordance with an embodiment of the present invention.

FIG. 3 shows an internal configuration of a switch in accordance with an embodiment of the present invention.

FIG. 4 and FIG. 5 show how the IPM having a snubber capacitor for surge reduction installed therein in accordance with an embodiment of the present invention is actually implemented.

FIG. 6 is a graph showing measured surge voltages of a conventional IPM.

FIG. 7 is a graph showing measured surge voltages of the IPM having a snubber capacitor for surge reduction installed therein in accordance with an embodiment of the present invention.

### DETAILED DESCRIPTION

Hereinafter, some embodiments will be described in detail with reference to the accompanying drawings. Identical or corresponding elements will be given the same reference numerals, regardless of the figure number, and any redundant description of the identical or corresponding elements will not be repeated. Throughout the description of the present invention, when describing a certain relevant conventional technology is determined to evade the point of the present invention, the pertinent detailed description will be omitted.

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the ideas and scope of the present invention.

The terms used in the description are intended to describe certain embodiments only, and shall by no means restrict the present invention. Unless clearly used otherwise, expressions in a singular form include a meaning of a plural form. In the present description, an expression such as “comprising” or “including” is intended to designate a characteristic, a number, a step, an operation, an element, a part or combinations thereof, and shall not be construed to preclude any presence or possibility of one or more other characteristics, numbers, steps, operations, elements, parts or combinations thereof.

Unless otherwise defined, all terms, including technical terms and scientific terms, used herein have the same meaning as how they are generally understood by those of ordinary skill in the art to which the invention pertains. Any term that is defined in a general dictionary shall be construed to have the same meaning in the context of the relevant art, and, unless otherwise defined explicitly, shall not be interpreted to have an idealistic or excessively formalistic meaning.

An intelligence power module (IPM) is an inverter module that is mostly used for driving a motor. In order to drive the IPM, a low-voltage signal (between about 3.3V and 5V) is first received by a drive IC in the IPM from a micro control unit (MCU), and the drive IC elevates the level of the received low-voltage signal to a high-voltage signal (about 15V) sufficient for driving IGBT and transfers the high-voltage signal to the IGBT.

The IGBT is turned on or off, depending on the transferred signal, to drive a motor.

Voltage applied between a P pin and an N pin of the IPM is typically about 300V, or sometimes up to 400V, depending on the system. By performing switching while the high voltage is applied between the P pin and the N pin, a surge voltage is applied to the high-side IGBT when the IGBT is turned off.

This surge voltage becomes greater when the voltage between the P pin and the N pin is greater or when the current flowing to the IGBT is greater or when a turn-off current is tilted by a greater angle. If the surge voltage is great, malfunction may be resulted, and if the surge voltage is greater than an internal voltages of the IGBT or HVIC, the IGBT or HVIC may malfunction or be destroyed.

Therefore, an embodiment of the present invention provides an IPM having a snubber capacitor for surge reduction installed therein.

Hereinafter, certain embodiments of the present invention will be described in detail with reference to the accompanying drawings.

FIG. 1 is a block diagram showing an IPM having a snubber capacitor for surge reduction installed therein in accordance with an embodiment of the present invention.

Referring to FIG. 1, an IPM 100 having a snubber capacitor for surge reduction installed therein in accordance with an embodiment of the present invention can include a drive IC 110, a switch 120 and a surge reducer 130.

The drive IC 110 can receive a first voltage signal from an MCU (micro controller unit) 10 and generate a second voltage signal. The MCU 10 can generate an IPM control signal. The drive IC 110 can receive the IPM control signal from the MCU 10. Here, the IPM control signal can include a voltage signal. For the convenience of description, the IPM control signal will be referred to as the first voltage signal in this specification.

The drive IC 110 can receive the first voltage signal and generate the second voltage signal. Here, the second voltage signal can include a signal for controlling the switch 120. In an embodiment, the first voltage signal can be smaller than the second voltage signal. For example, the first voltage signal can be between about 3.3V and 5V, and the second voltage signal can be 15V.

The switch 120 can receive the second voltage signal from the drive IC 110 and generate a motor driving signal for driving a motor 20 based on the second voltage signal. Once the motor driving signal is transferred to the motor 20, a minute control of the motor 20 becomes possible by the motor driving signal.

Connected in between the switch 120 and the motor 20, the surge reducer 130 SR can reduce a surge voltage. The surge reducer 130 in accordance with an embodiment of the present invention can be installed inside the IPM 100. Conventionally, a capacitor has been connected outside an IPM to reduce the surge. However, by connecting the capacitor outside the IPM, a length of a connecting member is increased and thus increases an inductor component (L) shown in the below [Equation 1], resulting in an increase of surge voltage (V_{L}). Therefore, an embodiment of the present invention presents installing the capacitor inside the IPM 100.

$${V}_{L} = L \frac{d I}{d t} \qquad [ Equation 1 ]$$

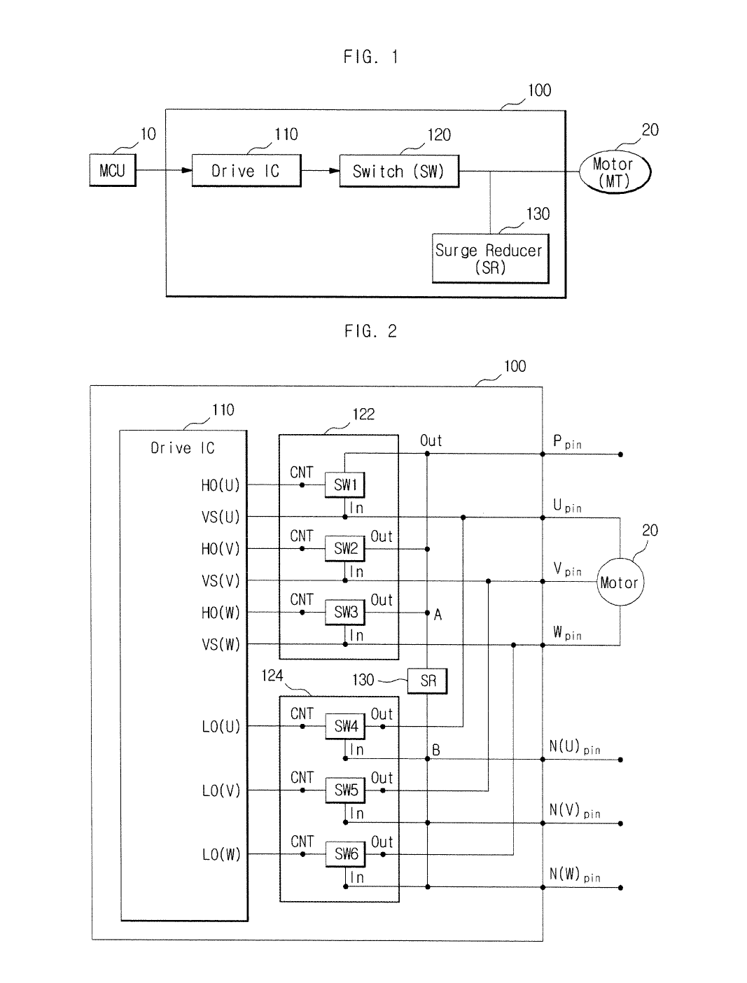

FIG. 2 shows an internal configuration of the IPM 100 having a snubber capacitor for surge reduction installed therein in accordance with an embodiment of the present invention.

Referring to FIG. 2, the switch 120 in accordance with an embodiment of the present invention can include a first sub-switch 122 and a second sub-switch 124.

The first sub-switch 122 can include a first switch SW1, a second switch SW2 and a third switch SW3, and the second sub-switch 124 can include a fourth switch SW4, a fifth switch SW5 and a sixth switch SW6.

The surge reducer SR can be connected to one end of the first sub-switch 122 and one end of the second sub-switch 124.

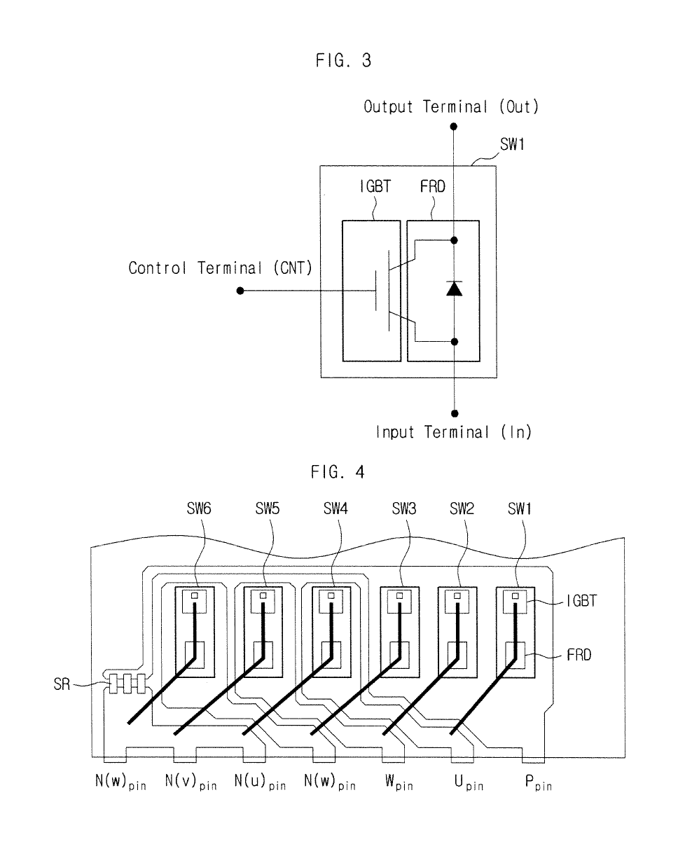

Referring to FIG. 3, the switches SW1, SW2, SW3, SW4, SW5, SW6 in accordance with an embodiment of the present invention can each include a control terminal (CNT), an input terminal (In) and an output terminal (Out), and an intensity of a signal outputted from the input terminal (In) to the output terminal (Out) can be adjusted by a signal transferred to the control terminal (CNT).

In one embodiment, the switches SW1, SW2, SW3, SW4, SW5, SW6 can each include at least one selected from the group consisting of GTO (Gate Turn-off Thyristor), MOSFET, IGBT (Insulated Gate Bipolar Transistor), MCT (MOS-Controlled Thyristor) and FRD, but the kind of switch shall not be restricted what is described herein.

Referring to FIG. 2 again, the control terminal (CNT) of the first switch SW1 can be connected with terminal HO(U) of the drive IC 110. The input terminal (In) of the first switch Sw1 can be connected with terminal VS(U) of the drive IC 110. The output terminal (Out) of the first switch SW1 can be connected with a P pin.

The control terminal (CNT) of the second switch SW2 can be connected with terminal HO(V) of the drive IC 110. The input terminal (In) of the second switch SW2 can be connected with terminal VS(V) of the drive IC 110. The output terminal (Out) of the second switch SW2 can be connected with the P pin.

The control terminal (CNT) of the third switch SW3 can be connected with terminal HO(W) of the drive IC 110. The input terminal (In) of the third switch SW3 can be connected with terminal VS(W) of the drive IC 110. The output terminal (Out) of the third switch SW3 can be connected with the P pin.

Moreover, the output terminal (Out) of the first switch SW1, the output terminal (Out) of the second switch SW2 and the output terminal (Out) of the third switch SW3 can be each connected with terminal A.

The control terminal (CNT) of the fourth switch SW4 can be connected with terminal LO(U) of the drive IC 110. The input terminal (In) of the fourth switch SW4 can be connected with an N(U) pin. The output terminal (Out) of the fourth switch SW4 can be connected with the input terminal of the first switch SW1 and the U pin.

The control terminal (CNT) of the fifth switch SW5 can be connected with terminal LO(V) of the drive IC 110. The input terminal (In) of the fifth switch SW5 can be connected with an N(V) pin. The output terminal (Out) of the fifth switch SW5 can be connected with the input terminal of the second switch SW2 and the V pin.

The control terminal (CNT) of the sixth switch SW6 can be connected with terminal LO(W) of the drive IC 110. The input terminal (In) of the sixth switch SW6 can be connected with an N(W) pin. The output terminal (Out) of the sixth switch SW6 can be connected with the input terminal of the third switch SW3 and a W pin.

Moreover, the input terminal (In) of the fourth switch SW4, the input terminal (In) of the fifth switch SW5 and the input terminal (In) of the sixth switch SW6 can be each connected with terminal B.

In summary, the U pin is connected by the input terminal (In) of the first switch SW1 and the output terminal (Out) of the fourth switch SW4 and is connected to the motor 20. The V pin is connected by the input terminal (In) of the second switch SW2 and the output terminal (Out) of the fifth switch SW5 and is connected to the motor 20. The W pin is connected by the input terminal (In) of the third switch SW3 and the output terminal (Out) of the sixth switch SW6 and is connected to the motor 20. The U pin, V pin and W pin can be each connected to the motor 20 and transfer the motor driving signal.

In an embodiment of the present invention, the surge reducer (SR) 130 can be connected in between the terminal A and the terminal B. As described above, the surge reducer 130 can be installed inside the IPM 100 and can be a capacitor, which can include an MLCC (multi-layer ceramic capacitor).

In order to install a capacitor for surge reduction in an IPM for home appliances, a lead frame needs to be designed so as to allow the capacitor to be inserted therein. However, there is a limitation in the size of the IPM for home appliances. The film capacitor, which is the capacitor for surge reduction used for various products, is too large to fit in the IPM. Therefore, the capacitor that can be installed in the IPM in accordance with an embodiment of the present invention can be a high voltage MLCC.

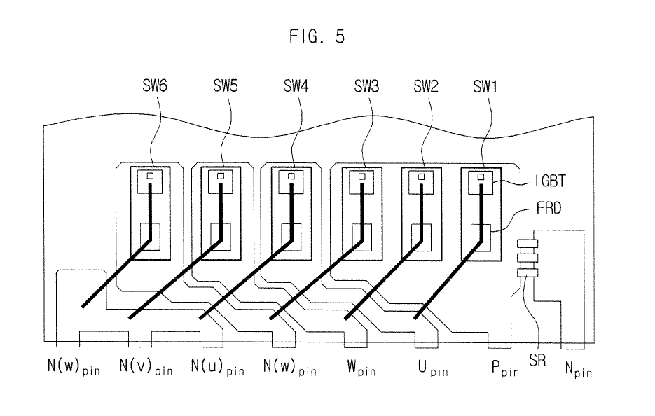

FIG. 4 and FIG. 5 show how the IPM having a snubber capacitor for surge reduction installed therein in accordance with an embodiment of the present invention is actually implemented.

Referring to FIG. 4, the first switch SW1 can include an IGBT and an FRD (Fast Recovery Diode). It can be seen that the output terminal of the first switch SW1 is connected with the P pin and the input terminal of the second switch SW2 is connected with the U pin. Here, the P pin is extended to be adjacent to the N(W) pin, N(V) pin and N(U) pin, and the surge reducer SR, i.e., an MLCC, is connected in between the P pin and the N(W), N(V) and N(U) pins. This corresponds to connecting the capacitor in between the terminal A and the terminal B in FIG. 2.

Referring to FIG. 5, it can be seen that the surge reducer SR, i.e., an MLCC capacitor, is connected in between the P pin and the N pin. By this configuration, a connection route can be shortened than extending the P pin. Moreover, with the MLCC capacitor, it is possible to connect more than one capacitors in parallel and to adjust the capacitance according to the property of the product to be used by a user.

[Table 1] below shows the effect of the IPM 100 having a snubber capacitor for surge reduction installed therein in accordance with an embodiment of the present invention.

TABLE 1

| Condition | Capacitance | Surge Voltage |
|---|---|---|
| Without Capacitor | | 496 V |
| With External Film Capacitor | 100 nF | 436 V |
| With Internal MLCC | 3 nF | 432 V |

Referring to [Table 1], it can be seen that the surge voltage is 496V when there is no capacitor. Then, it can be seen that the surge voltage becomes 426V when a 100 nF capacitor is connected outside the IPM. However, the 100 nF film capacitor is too large to be installed in today's products, which become increasingly smaller. Moreover, the 100 nF film capacitor is expensive enough to increase the unit prices of the products. In an embodiment of the present invention, the surge voltage of 432V can be obtained by using a 3 nF capacitor.

Even if a PCB pattern is made to be as short as possible in order to connect the capacitor for surge reduction as close as possible to an outside of the IPM, the capacitor for surge reduction is inevitably distanced from the IPM due to its position outside the IPM, and thus surge reduction becomes less effective than when the capacitor is installed inside the IPM. Accordingly, a capacitor having a smaller capacitance may be used because installing the capacitor inside the IPM has a greater surge reduction effect than connecting the capacitor outside the IPM.

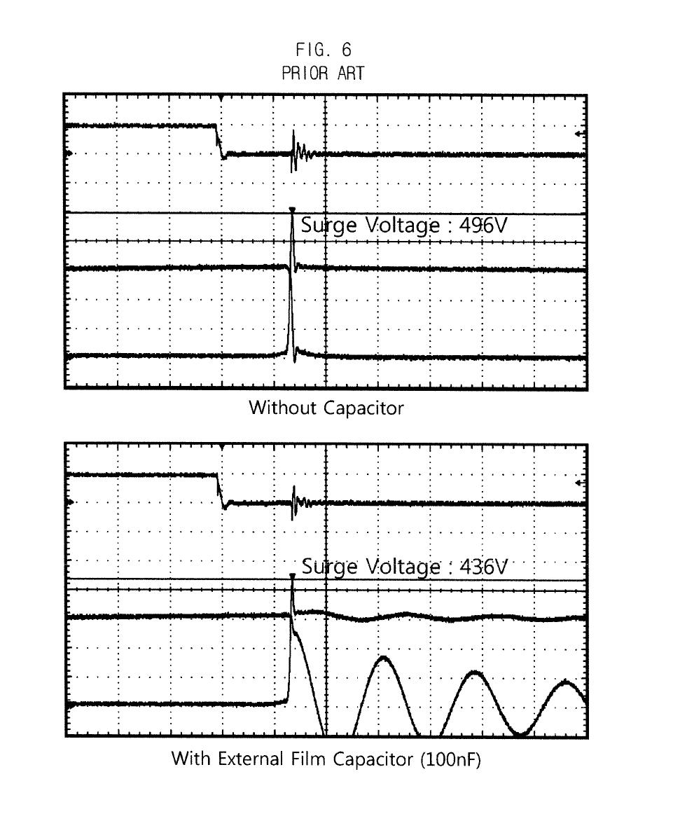

FIG. 6 is a graph showing measured surge voltages of a conventional IPM.

Referring to FIG. 6, it can be seen that the surge voltage is 496V when there is no capacitor. Moreover, it can be seen that the surge voltage is 436V when an external film capacitor (100 nF) is introduced.

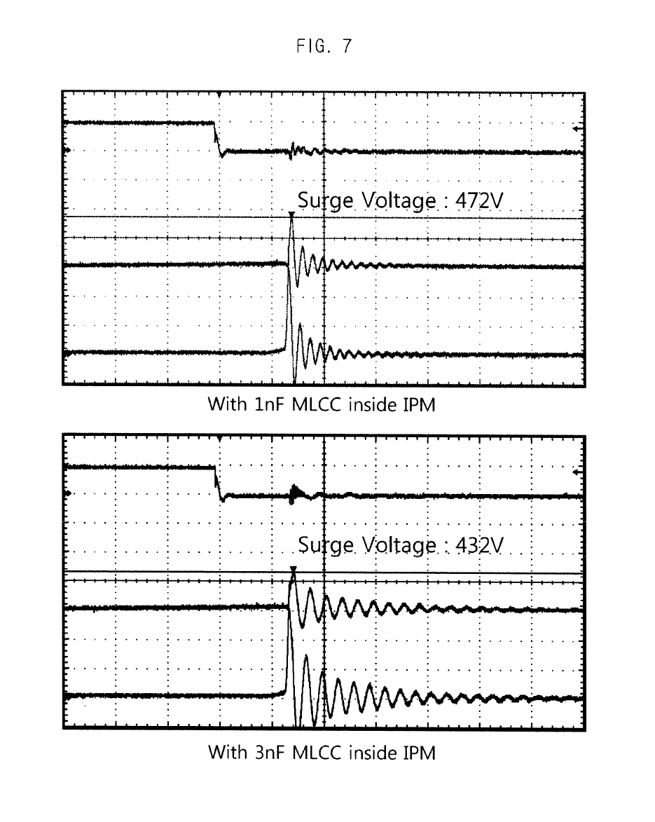

FIG. 7 is a graph showing measured surge voltages of the IPM 100 having a snubber capacitor for surge reduction installed therein in accordance with an embodiment of the present invention.

Referring to FIG. 7, it can be seen that the surge voltage is 472V when an MLCC having the capacitance of 1 nF is installed inside the IPM 100. Moreover, it can be seen that the surge voltage is 432V when an MLCC having the capacitance of 3 nF is installed inside the IPM 100.

As a result, the present invention allows a capacitor having a small capacitance to be installed inside an IPM to significantly reduce the surge voltage.

An embodiment of the present invention can provide home appliances including an IPM having a snubber capacitor for surge reduction installed therein. The home appliances can include any home appliances using a motor, for example, washing machines, refrigerators, vacuum cleaners, etc., but the scope of the present invention shall not be restricted any particular home appliances.

Although an embodiment of the present invention has been described hitherto, it shall be appreciated that the present invention can be variously modified and permutated by those of ordinary skill in the art to which the present invention pertains by supplementing, modifying, deleting and/or adding an element without departing from the technical ideas of the present invention, which shall be defined by the claims appended below. It shall be also appreciated that such modification and/or permutation are also included in the claimed scope of the present invention.

What is claimed is:

1. An intelligent power module having a snubber capacitor for surge reduction installed therein, comprising:
a drive IC configured to receive a first voltage signal from a micro controller unit and generate a second voltage signal;
a switch configured to receive the second voltage signal from the drive IC and generate a motor driving signal for driving a motor based on the second voltage signal; and
a surge reducer connected in between the switch and the motor and configured to reduce a surge voltage.

2. The intelligent power module of claim 1, wherein the surge reducer is installed inside the intelligent power module.

3. The intelligent power module of claim 1, wherein the surge reducer comprises a capacitor, and
wherein the capacitor is a multi-layer ceramic capacitor (MLCC).

4. The intelligent power module of claim 3, wherein the capacitor has more than one capacitor connected in parallel therein.

5. The intelligent power module of claim 4, wherein a capacitance of the capacitor is adjustable according to a request by a user.

6. The intelligent power module of claim 1, wherein the switch comprises a first sub-switch and a second sub-switch, and
wherein the surge reducer is connected to one end of the first sub-switch and one end of the second sub-switch.

7. The intelligent power module of claim 6, wherein the first sub-switch comprises a first switch, a second switch and a third switch, and the second sub-switch comprises a fourth switch, a fifth switch and a sixth switch,
wherein one end of the surge reducer is connected to an output terminal of the first switch, an output terminal of the second switch and an output terminal of the third switch, and
wherein the other end of the surge reducer is connected to an input terminal of the fourth switch, an input terminal of the fifth switch and an input terminal of the sixth switch.

8. The intelligent power module of claim 7, wherein an input terminal of the first switch, an input terminal of the second switch and an input terminal of the third switch are each connected with the motor.

9. The intelligent power module of claim 7, wherein the first switch, the second switch, the third switch, the fourth switch, the fifth switch and the sixth switch each comprise at least one selected from the group consisting of GTO (Gate Turn-off Thyristor), MOSFET, IGBT (Insulated Gate Bipolar Transistor) and MCT (MOS-Controlled Thyristor).

10. The intelligent power module of claim 1, wherein the first voltage signal is smaller than the second voltage signal.

11. A home electronic appliance comprising the intelligent power module of claim 1.
